(19) United States
(12) Patent Application Publication
(10) Pub. No.: US 2008/0242347 A1
(43) Pub. Date: Oct. 2, 2008

(54) Fast multiradio context switching

(75) Inventors: Tommi Zetterman, Helsinki (FI); Jaakko Varteva, Veikkola (FI); Antti Piipponen, Tampere (FI); Kalle Raiskila, Vantaa (FI)

Correspondence Address: HARRINGTON & SMITH, PC, 4 RESEARCH DRIVE, SHELTON, CT, 06484-6212, US

(73) Assignee: Nokia Corporation

(21) Appl. No.: 11/731,084

(22) Filed: Mar. 30, 2007

(51) Int. Cl. H04M 1/00; H03D 3/18

(52) U.S. Cl. 455/552.1; 370/465; 375/295; 455/101; 455/553.1; 710/8

(57) ABSTRACT

An apparatus, computer program product and method concern first and at least second radios adapted to operate according to respective first and second wireless radio systems, and which share hardware. While the first radio is inactive, first hardware configuration data HCD for the first radio is written to a first configuration register set. While the second radio is inactive, second HCD for the second radio is written to a second configuration register set. The first radio is switched to active by selecting the first configuration register and configuring at least the shared hardware according to the first HCD of the first configuration register set. The second radio is switched to active and the first radio is switched to inactive by selecting the second configuration register set and configuring at least the shared hardware according to the second HCD of the second configuration register set. For a tangible result, the respective radios transmit via according to the respective wireless radio systems.

### TECHNICAL FIELD

This disclosure relates generally to software defined radios, and more particularly to a method and apparatus for enabling efficient RF hardware sharing in multi-radio devices.

### BACKGROUND

In software defined radios (SDR), the Radio Frequency (RF) hardware (HW) is typically used as a radio transceiver for variable radio standards or systems, such as GSM (global system for mobile communication), WCDMA (wideband code division multiple access), WLAN (wireless local area network), BT (Bluetooth), DVB-H (digital video broadcast for handheld devices), WiMax (wireless broadband), GPS (global positioning system), and Galileo. This raises a need for general-purpose, configurable RF hardware blocks that are capable of operating with the widely distinct requirements of different radio standards. This need for a wide range of configurability and tunability options increases the number of different configuration options which have to be modified when configuration settings are changed. This means a greater number of configuration settings that are required to reconfigure the shared RF HW blocks for the different radio modes.

On the other hand, some devices use multiple radios capable of simultaneous operation. To cost-effectively implement this kind of ‘multiradio’ device, the RF HW has to be shared between simultaneously active radios whenever possible. To make this sharing feasible, fast RF HW configuration switch times from one radio mode to another radio mode (i.e. radio context switch time) is required. However, the radio context switch time typically increases with an increasing number of configuration settings in the SDR device.

FIG. 1 illustrates an ideal situation where radio context switch time is minimal and thus no conflicts are present. In FIG. 1, Radios 1 and 2 are active during the times indicated by the darkened blocks in their respective row. Because the interval between the times that Radio 1 and 2 are active is sufficiently long in each instance of a switch, the context switching by which the shared HW is reconfigured to the other radio does not cause a delay in the time at which the newly-configured radio can begin to be used.

However, FIG. 2 illustrates further detail where the context switching time, illustrated as “writing new configuration” does impact radio operation. As can be seen in the rightmost radio context switching time, represented by block 500, a conflict occurs between the first radio device and the second radio device. The new configuration parameters are still being written to the configuration register set during the time the device should be switched to the TDMA mode of Radio 1. Radio 1 cannot become active until all of those new parameters are written else the shared HW will not be properly configured. This is a problem that embodiments of this invention address.

In practice, radio context switching is accomplished by writing new configuration values to the RF HW control registers. Unfortunately, with general purpose RF HW blocks appearing in SDR devices, the amount of control data is large and can typically involve modifying up to several hundred configuration settings. This can be a time consuming process and can make writing to the configuration register the critical factor in the radio context switch time. To make matters worse, future designs are incorporating RF hardware that use Complementary Metal-Oxide Semiconductor (CMOS) devices and because RF hardware typically requires more calibration and tuning when going to deep submicron CMOS, this increases the already large number of configurations that have to be modified. This is because the calibration settings, which differ from one wireless radio system/protocol to another, are a part of the configuration parameters that are written to the control registers. Unfortunately, a consequence of this increasing amount of configuration data is that the spare time between activity periods of two different radios may be too short to switch between different RF HW configurations.

Traditionally, SDR's have included dedicated RFHW for each simultaneously active radio. As such, configuration parameters are written once before the radio connection is activated and thus, configuration time is not critical because the RF HW is not shared between the two active radios (i.e. no need for time-critical radio context switch). Unfortunately however, this traditional solution will not be feasible in future consumer multiradio devices, where there may be many more simultaneously active connections than currently available. As an example, consider the situation where GPS for navigation, Bluetooth for local connection, DVB-H for streaming video and GSM/WCDMA for active phone call are all simultaneously active in multiradio device. If RF HW sharing and radio context switching are not used, than each simultaneously active radio should be allocated its own dedicated RF HW. This tends to increase the device cost making it less competitive compared to devices that share RF HW. In this case, with RF HW sharing and fast switching, three physical receiver chains would typically be needed to implement these four simultaneous receiver chains. Some examples of other possible use cases gaining fast switching are WLAN+BT, GSM+BT, DHB−H+WLAN/BT.

Additionally, while some multiradio devices may have their configuration hard wired for simultaneously used radio modes, making switching from one radio to another fast, this type of HW is typically limited to those predefined radio modes and does not usually scale to configurability requirements needed in SDR systems. To adapt this approach to more than two radios entails separate HW for the whole of each radio, which would tend to increase expense and bulk of the resulting device.

### SUMMARY

In accordance with one embodiment is provided a method that includes, providing a device that includes a first radio adapted to operate according to a first wireless radio system and at least a second radio adapted to operate according to a second wireless radio system, the first radio and second radio each including shared hardware. While the first radio is inactive, first hardware configuration data for the first radio is written to a first configuration register set. While the second radio is inactive, second hardware configuration data for the second radio is written to a second configuration register set. The first radio is switched to active by selecting the first configuration register, configuring at least the shared hardware according to the first hardware configuration data of the first configuration register set, and communicating via the first radio according to the first wireless radio system. The second radio is switched to active and the first radio is switched to inactive by selecting the second configuration register set, configuring at least the shared hardware according to the second hardware configuration data of the second configuration register set, and communicating via the second radio according to the second wireless radio system.

In accordance with another embodiment is provided an apparatus. The apparatus includes a first radio and at least a second radio that share hardware components. The first radio is adapted to operate according to a first wireless radio system and the second radio is adapted to operate according to a second wireless radio system. The apparatus further includes a processor and a memory coupled to the processor. The memory includes at least a first configuration register set for storing a first group of parameters and a second configuration register set for storing a second group of parameters. The apparatus further includes configuration selection logic, coupled to the processor and to the first and second configuration register sets. The configuration selection logic is adapted to switch between the first radio being active and the second radio being active by configuring at least the shared hardware according to the group of parameters of the selected first and second configuration register sets.

In accordance with another embodiment is provided a computer program product that includes program instructions embodied on a tangible computer-readable medium for switching between a first and a second radio that shares hardware with one another. Execution of the program instructions result in operations that include writing first hardware configuration data for a first radio to a first configuration register set, while the first radio is inactive. The first radio is adapted to operate according to a first wireless radio system. While a second radio adapted to operate according to a second wireless radio system is inactive, the actions include writing second hardware configuration data for the second radio to a second configuration register set. The first radio is switched to active by selecting the first configuration register, configuring at least the shared hardware according to the first hardware configuration data of the first configuration register set, and communicating via the first radio according to the first wireless radio system. The second radio is switched to active and the first radio is switched to inactive by selecting the second configuration register set, configuring at least the shared hardware according to the second hardware configuration data of the second configuration register set, and communicating via the second radio according to the second wireless radio system.

In accordance with another embodiment is provided a device that includes: a memory that has a first configuration register set and a second configuration register set; shared hardware that is selectively configurable for a first wireless radio radio system and for at least a second wireless radio radio system; a controller that is configured to write first hardware configuration data to the first configuration register set and to write second hardware configuration data to the second configuration register set; and a configuration selection switch that is adapted to selectively couple the first and the second configuration register sets to the shared hardware and thereby configure the shared hardware with the first hardware configuration data for communication according to the first wireless radio system, and with the second hardware configuration data for communication according to the second wireless radio system.

In accordance with another embodiment is provided an apparatus that includes first radio means and at least second radio means that share hardware components with one another. The first radio means is adapted to operate according to a first wireless radio system and the second radio means is adapted to operate according to a second wireless radio system. The apparatus also includes processing means and memory means coupled to the processing means. The memory means includes at least a first register means for storing a first group of parameters and a second register means for storing a second group of parameters. Also, the apparatus includes selection means, coupled to the processing means and to the first and second register means, where the selection means is adapted to switch between the first radio means being active and the second radio means being active by configuring at least the shared hardware components according to the group of parameters of the selected first and second register means. In a particular embodiment, the apparatus described immediately above is characterized in that the first radio means is a first radio; the second radio means is a second radio; the processing means is a digital data processor; the memory means is a computer readable memory; the first register means is a first configuration register set; the second register means is a second configuration register set; and the selection means is a switch.

### BRIEF DESCRIPTION OF THE DRAWINGS

The foregoing and other features and advantages of the present invention should be more fully understood from the following detailed description of illustrative embodiments taken in conjunction with the accompanying Figures in which like elements are numbered alike in the several Figures:

FIG. 1 is a block diagram illustrating an ideal radio context switching scheme for two simultaneously active radios.

FIG. 2 is a block diagram illustrating a radio context switching scheme for two simultaneously active radios, in accordance with the prior art.

FIG. 3A is a block diagram illustrating one embodiment of an apparatus for enabling fast radio context switching, in accordance with an embodiment of the invention.

FIG. 3B is a schematic block diagram illustrating exemplary functional blocks of a multi-radio device using shared hardware according to an embodiment of the invention.

FIG. 4 is a block diagram illustrating one embodiment of a radio context switching scheme for two simultaneously active radios, in accordance with an embodiment of the invention.

FIG. 5 is a block diagram illustrating an alternative embodiment of a radio context switching scheme for two simultaneously active radios, in accordance with an embodiment of the invention.

FIG. 6 is a sequence diagram illustrating the initialization and switching scheme between two simultaneously active radios, in accordance with an embodiment of the invention.

FIG. 7 is a block diagram illustrating one embodiment of the method for dynamically configuring RF HW, in accordance with an embodiment of the invention.

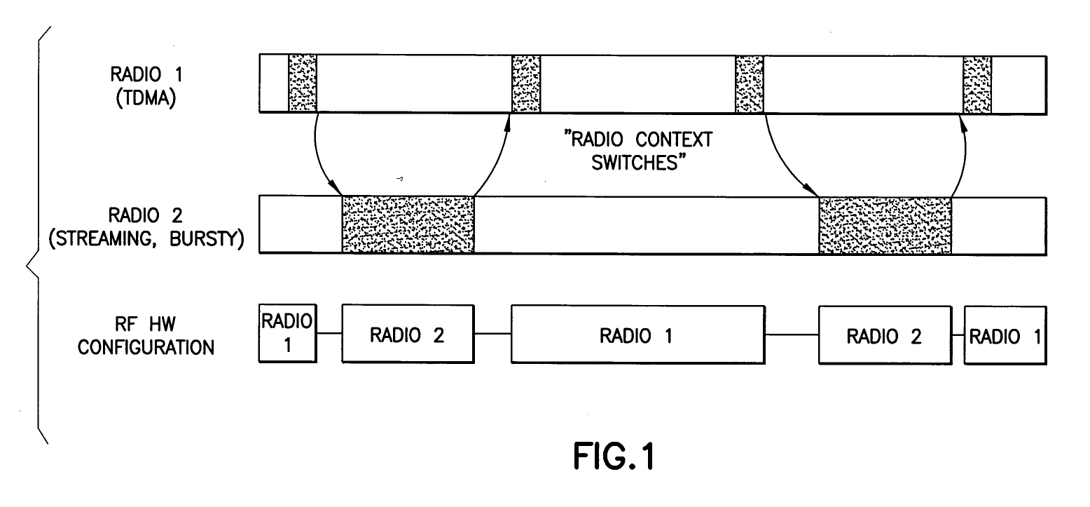

### DETAILED DESCRIPTION

It should be appreciated that in GSM/WCDMA, where one system must periodically scan for base stations of the other system, there exist idle frames during which there is enough time to switch between systems, thus negating the necessity for fast context switching. Some proposed digital Field Programmable Gate Array (FPGA) architectures use similar schemes (for example: Xilinx Virtex) to enable partial reconfiguration, where configuration data is loaded into part of the logics chip, and new configuration data is switched on by changing the active configuration memory. The present invention differs from existing work in FPGA in that the context switching is used in the RF HW domain by dynamically changing the configuration between two (or more) simultaneously active radio modes. Moreover, in addition to routing the data used in FPGA (i.e. signal path routing and logic configuration), radio modes typically have radio-specific information associated with them (such as, RF block calibration data, transmitter gain setting, etc.) which may be stored and restored during context switching.

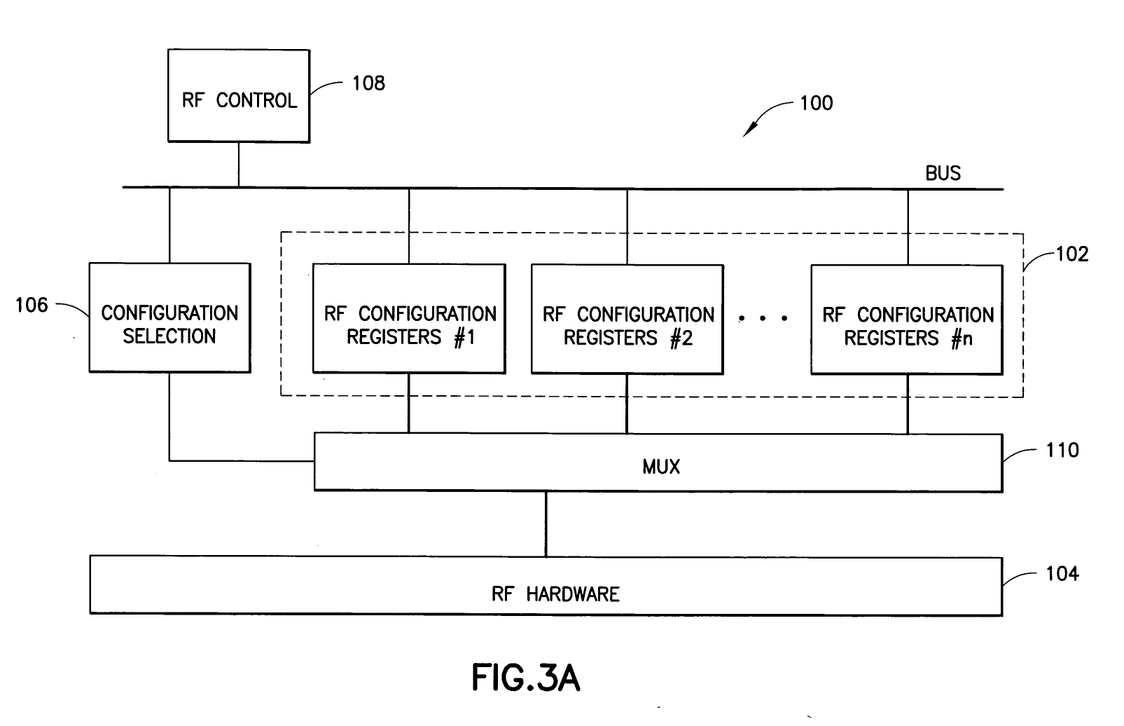

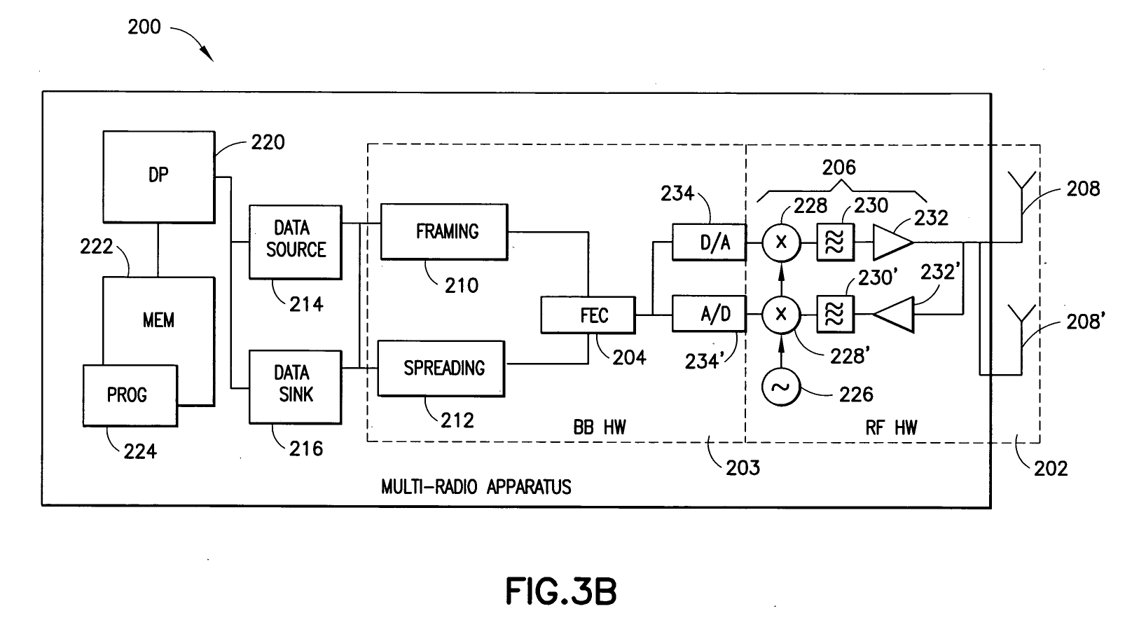

In accordance with an embodiment of the invention, in a multiradio device capable of sharing configurable RF HW with a plurality of simultaneously active radios, an apparatus 100 for dynamically configuring the RF HW is provided. Referring to FIG. 3A, one embodiment of the apparatus 100 includes a plurality (i.e. two or more) of independent configuration register sets 102, for each set of RF HW 104 in the multiradio device, wherein one register set 102 is present for each simultaneously active radio. The configuration settings related to each active radio connection may then be stored in a separate register set 102 and the radio context switching may be performed with a single configuration write action by selecting the active register set 102.

The apparatus 100 further includes configuration selection logic 106 and an RF control unit 108 wherein the configuration selection logic 106 can quickly activate a new RF HW 104 configuration when the radio context switching occurs and the RF control unit 108 can configure the RF HW 104 by writing the configuration register settings. Additionally, the RF control unit 108 may be configured to switch RF HW 104 from one mode to another mode at a predetermined time. It should be appreciated that the RF HW 104 of FIG. 3A represents HW shared by the various radios, and there typically will be also dedicated HW for each of the radios that is not shared. The parameters written into the various RF configuration registers 102 at least relate to the shared HW 104, but may also include parameters for the dedicated HW without departing from these teachings.

Consider the schematic diagram of a multi-radio apparatus 200 shown in FIG. 3B. The multi-radio apparatus 200 may alternatively be broadly termed a wireless device or a user equipment. The apparatus 200 includes various hardware of which are shown shared and dedicated functional blocks. The apparatus 200 shows two radios though it is understood, from the examples given above, that more may be present. For convenience the hardware is grouped into RF HW 202 and baseband BB HW 203. Hardware in the RF HW block 202 and/or the BB HW block may be shared, but it is understood that in current multi-radio SDRs that share HW components the majority if not all of the shared HW lies within the RF HW block 202. Generally, the dividing line between the RF HW block 202 and the BB HW block 203 is the one sample per symbol boundary. The RF HW 202 includes a transceiver 206, of which is illustrated in simplified view as including a voltage controlled oscillator 226 that upconverts a signal to be transmitted to RF or downconverts a received RF signal to BB via mixers 228, 228′, filters 230, 230′, and power amplifiers 232, 232′. These are all shared HW in FIG. 3B. In SDRs according to embodiments of this invention, the parameters stored in the different configuration register sets set the frequency of the VCO 226, the pass band of the filters 230, 230′, and the gain of the amplifiers 232, 232′, as one or more of these HW components are controlled differently for different radio systems depending on which radio is active at a given instant. It is understood that other RF HW configurable in a SDR is included in the RF HW 202 though not illustrated, such as intermediate frequency IF upconverters/downconverters for an IF between BB and RF, and phase rotators. Further in the RF HW block 202 is one or more antennas 208, 208′ (two shown) of which at least one is shared when communicating using the different radio systems that differentiate operation of the two radios. Beamforming among these antennas may also differ for the different radios and be configured by the parameters stored in the configuration register sets. There may also be shared HW in the BB HW block 203, such as the illustrated coding block 204 that encodes/decodes with a forward error correction code FEC, interleavers (not shown), digital samplers/interpolators/decimators (not shown) and the like. Different wireless systems may use different FEC schemes, puncture schemes, interleaving schemes, data rates and the like, and therefore the associated BB HW components that might be shared are controlled differently by specific parameters in the different configuration register sets. Also shown as within the BB HW block 203 is a digital to analog converter D/A 234 for the uplink direction and an analog to digital converter D/A for the downlink direction.

Dedicated HW for the different radios includes a framing block 210 for a TDMA (time division multiple access) radio and a spreading block 212 for a bursty radio. It is understood that some radio systems (e.g., GSM) may use both framing and spreading (in which case the spreading block 212 would be a shared HW block), but FIG. 3B is for illustration only and kept simple for clarity of description. In some embodiments two specific radios may not share an antenna, but the concept remains that a pair of radios share at least some RF HW.

Now a first radio of FIG. 3B includes the chain from the framing block 210, the FEC block 204, the converters 234, 234′, the transceiver 206 and the two antennas 208, 208′. A second radio includes the chain from the spreading block 212, the FEC block 204, the converters 234, 234′, the transceiver 206 and the two antennas 208, 208′. The different systems followed by the first and second radio require different settings for shared HW such as the radio frequency of the VCO 226/mixers 228, 228′ and gain of the amplifiers 232, 232′, for example. These represent configuration parameters for the different radios, and those skilled in the art will recognize that the entire set of configuration parameters to set either radio in compliance with the wireless radio system over which it is to communicate are quite extensive beyond those noted above by example. A bursty radio system will have assigned spreading codes and a highly variable gain that changes with location of the apparatus 200 and the quality of the channel over which it communicates. A TDMA radio system will have parameters related to frame/superframe size, spacing between frames, pilot tones within the frames, and the like. Both might require the apparatus to monitor a paging channel during discontinuous reception and/or a broadcast channel of a neighboring node B/base station at specific times and frequencies that change frequently. The parameter set necessary for a single wireless system is both large and dynamic; many of the parameters of the set are not fixed and must be updated by the apparatus 200 dynamically based on current conditions or instructions from the network.

To complete the description of the multi-radio apparatus 200, there is also a data source 214 and data sink 216 which may be a transducer (microphone/speaker) in the case of voice communications, generally not considered part of the wireless radio functions. Also included is a processor (DP) 220, a memory (MEM) 222 that stores a program (PROG) 224, and a suitable radio frequency (RF) transceiver 10D forbidirectional wireless communications with a node B/base station, an access point (WLAN), another wireless device (e.g., Bluetooth, WLAN), etc. In the MEM 222 are (at least) two separate and independent configuration register sets, each storing parameters for one of the radio systems followed by one of the respective radios when that radio is active. It is convenient to refer to these as register sets as opposed to simply a register since traditionally each parameter or grouping of closely related parameters is considered to be stored in a single register. As above, at least those parameters relevant to the shared HW is stored in the associated configuration register set though all parameters may be stored.

Assume a simple implementation wherein a first configuration register set is dedicated to the first radio that operates using wireless radio system X (e.g., TDMA) and a second configuration register set is dedicated to the second radio that operates with wireless radio system Y (e.g., CDMA). At some point the apparatus 200 writes the parameter set for system X to the first configuration register set (such as by the RF control block 108, which may be a part of the DP 220 or a processor of a system-on-a-chip SoC separate from the main DP 220). At this point there is no change to the shared HW, only parameters are stored in the MEM 222. Sometime thereafter the apparatus 200 uses the first radio by configuring it from the parameters stored in the first configuration register set and the first radio becomes active. The second radio is inactive, since both radios require use of the shared HW which can only be configured for one wireless radio system/one radio at a time. However, unlike the prior art there is nothing to prevent the apparatus 200 from writing (using the RF control 108/DP 220 as above) parameters for the second radio/second wireless radio system to the second configuration register set while the first radio is active. Unlike the prior art, writing to a configuration register set is not linked to a context switch from one radio to another; writing to a configuration register set other than the one currently associated with an active radio is independent of a context switch of active radios.

Now assume that all parameters for the second radio are written into the second configuration register set. At some time the apparatus 200 switches from the first radio to the second radio (e.g., moving from an area with only one network type to an area with only the other network type). In the prior art SDRs the new parameter set was written to the configuration register set, delaying the time at which the second radio could become active. In this example of the invention a single write command from the DP 220/RF Control 108 causes the already-populated second configuration register set to reconfigure the shared HW with those parameters, minimizing the time it takes to change over that shared HW from the first radio system to the second radio system.

Configuration settings for system Y have to be completed before switching the second radio on (e.g. before start of the frame/time slot). Because configuration setting can be prepared to a (inactive) configuration register set while some other radio system X uses the shared RF HW, timing constraints for configuration data writing are relaxed as compared to the situation when all changes have to be done during a shorter period after X has stopped transmission/reception and before Y needs to start it's transmission/monitoring. The configuration selection 106 (e.g., a switch) activates configuration settings for system Y before the second radio is “turned on” for transmission/monitoring (e.g. before start of its first frame/slot). The configuration selection module 106 is controlled by the RF control 108, and context selection using two configuration register sets avoids the tighter scheduling constraint of the prior art (e.g. write new parameters only when neither first nor second radio uses the RF HW), and uses only a single write action for context switching, compared to the possibly huge amount of data written to configuration registers. The active configurafion register set defines the state of the RF HW, the inactive configuration register set does not have any influence to the RF HW. The multiplexer MUX 110 of FIG. 3A selects the configuration register values/parameters that are wired to the RF HW 104 at any given instant.

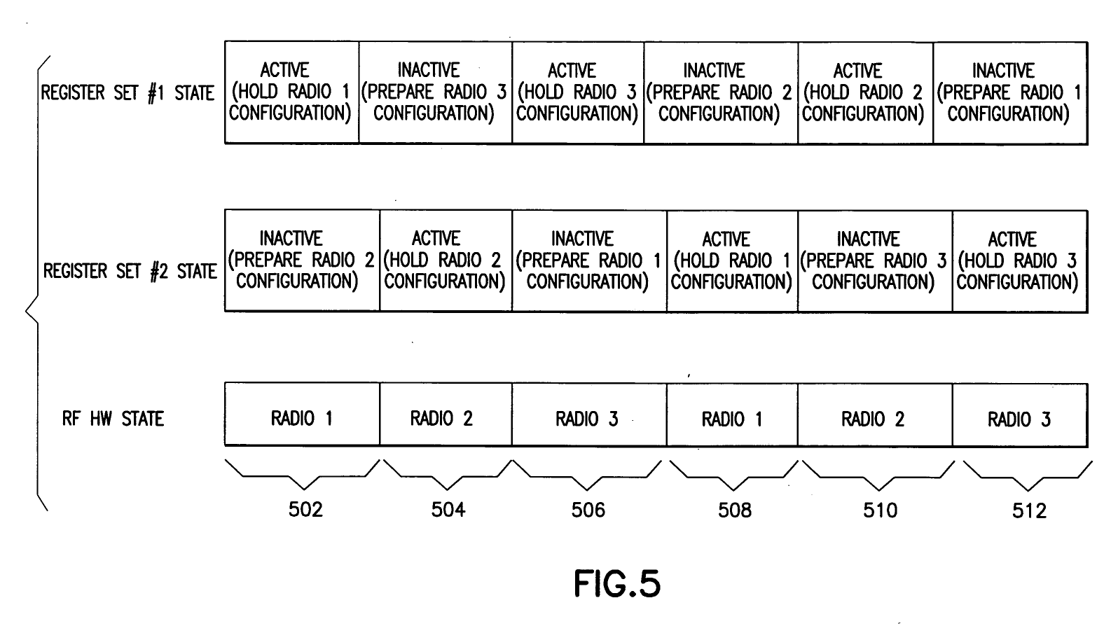

For only two radios, there may be a configuration register set dedicated to each. For more than two radios, at any given instant one configuration register set might be associated with whichever radio is active at the moment, and the other configuration register set may be associated with any other radio, preferably that radio deemed most likely to be switched to next. In both instances each of the configuration register sets is associated with an active radio, just at different times and for different radios. In the latter implementation a single configuration register set may be associated with more than one of the radios over a period of time, but understanding that at any instant it will be associated with only one radio. This is seen further at FIG. 5 below.

In general, the exemplary embodiments of this invention may be implemented by computer software (PROG 224) executable by the DP 220/RF controller 108 of the apparatus 100/200, or by hardware, or by a combination of software and/or firmware and hardware.

In general, the various embodiments of the apparatus 100/200 can include, but are not limited to, cellular telephones, personal digital assistants (PDAs) having wireless communication capabilities, portable computers having wireless communication capabilities, image capture devices such as digital cameras having wireless communication capabilities, gaming devices having wireless communication capabilities, music storage and playback appliances having wireless communication capabilities, Internet appliances permitting wireless Internet access and browsing, as well as portable units or terminals that incorporate combinations of such functions.

The MEM 222 maybe of any type suitable to the local technical environment and may be implemented using any suitable data storage technology, such as semiconductor-based memory devices, magnetic memory devices and systems, optical memory devices and systems, fixed memory and removable memory. The DP 220/RF Controller 108 may be of any type suitable to the local technical environment, and may include one or more of general purpose computers, special purpose computers, microprocessors, digital signal processors (DSPs), processors based on a multi-core processor architecture, and processor of a SoC under control of a main processor running an operating system, as non-limiting examples.

In accordance with the present invention, a method for dynamically configuring the RF HW is provided and includes controlling the RF HW to rapidly change the RF HW configuration from one radio mode to another during runtime. As discussed hereinabove, this may be accomplished by introducing a plurality (i.e. two or more) of independent configuration register sets for each RF HW, wherein one register set is typically present for each simultaneously active radio. This allows configuration settings related to each active radio connection to be stored in a separate register set and the radio context switching to be performed with a single configuration write action by selecting the active register set. Thus, the writing of configuration data is no longer a time critical action because each parallel configuration can be prepared to its own register set at any time, as long as it is ready before the radio connection is needed and the time it takes does not affect the radio context switch time.

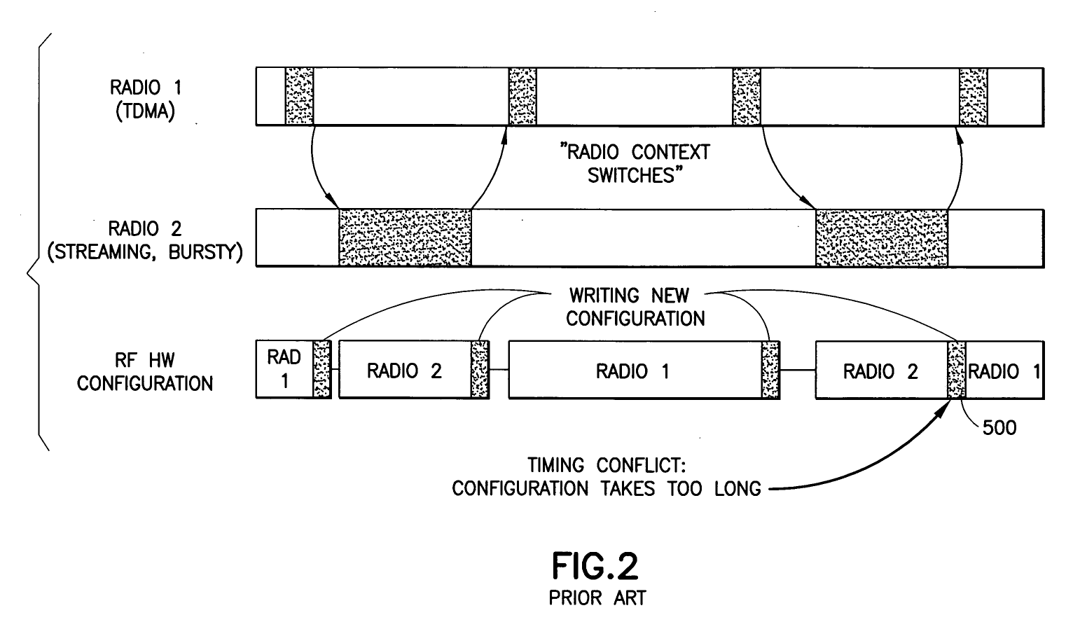

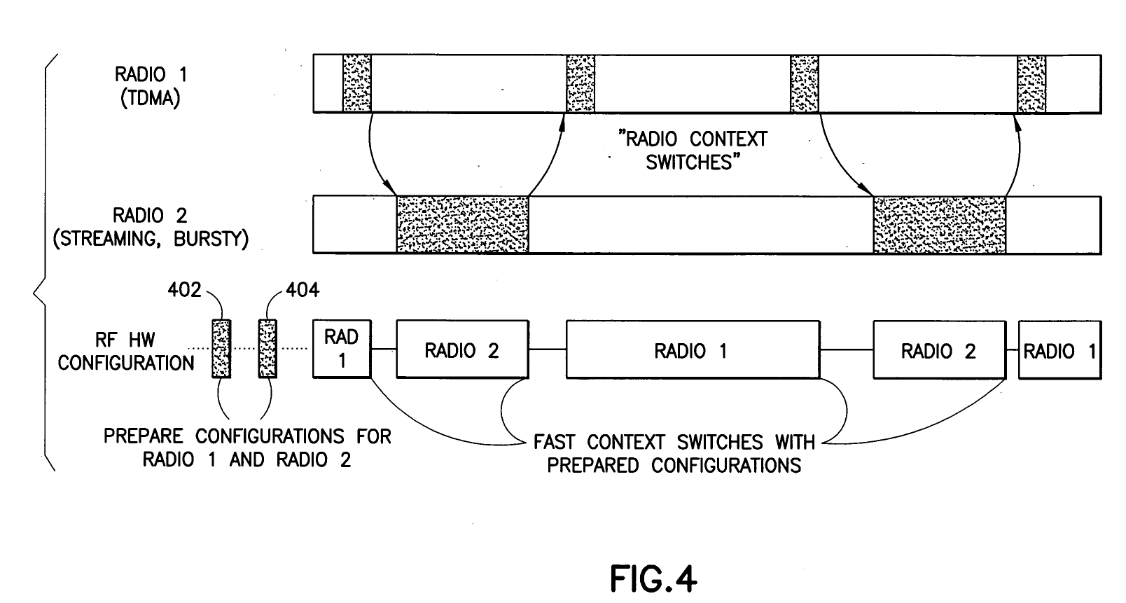

Thus, as shown in FIG. 4 during the radio context switching, a single write operation can select a new active configuration quickly. It is contemplated that apparatus 100 may include any number of simultaneously active radios and configuration register sets suitable to the desired end purpose and thus configuration data for N number of radios can be written to N number of configuration registers, as desired (where N is an integer greater than one). Compare FIG. 4 to FIG. 2. In FIG. 2, the “writing new configuration” blocks were tied to switching from one active radio to another. In FIG. 4, new configurations are written 402 into the first configuration register set and also written 404 into the second configuration register set independent of switching between those radios as active. While both write processes 402, 404 into the different register sets (shown in FIG. 4 as “prepare configuration”) occur prior to either radio 1 or radio 2 becoming active, it is clear that the configuration register set not in use by the active radio can be written to at any time, and the dynamically variable parameters kept continuously updated as the need may be.

Referring to FIG. 5, an alternative embodiment of the method involves implementing two configuration register sets in an RF IP block for three alternating active radios, one configuration register set which is active and one which is inactive. As such, in this case the radios must share the configuration register sets. The active configuration register set defines the current configuration of the RF HW and contains the settings of the currently active radio system, while the inactive register set can be used to prepare the configuration for the next active radio. When radio context switching takes place, active and inactive register sets change roles. The difference between this embodiment and the first embodiment is that when more than two simultaneous radios share the same HW, there are no dedicated control registers for each radio. Thus, if more than two different radios use the HW between the activity periods, the configuration data for one of the radios is lost and has to be completely rewritten. FIG. 5 illustrates one simple example of this alternative embodiment, which involves three alternating radio systems sharing the same RF HW and shows how the active and inactive periods are used.

Specifically, at a first interval 502 radio 1 is active using parameters from register set #1, and the apparatus 100/200 is free to update/populate the inactive register #2 with the parameters necessary to configure radio 2. At a context switch between the first interval 502 and a subsequent second interval 504, radio 2 is switched to active using the parameters of register set #2 and radio 1 is made inactive. This means that register set #1 is now not associated with an active radio, and it is prepared for configuring radio 3. At the transition to a third interval 506, radio 3 becomes active using the parameters now in the register set #1, radio 2 is inactive and parameters for radio 1 can be written into inactive register #2. Radio 1 is again made active in a fourth interval 508 using the parameters now in register #1, and so forth for fifth interval 510 and sixth interval 512. As can be seen, radio 1 is active in the first 502 and fourth 508 intervals but using different register sets, so the register sets are not dedicated to a particular radio. The teachings of FIG. 5 are readily extended to any number of radios beyond three, which is used by example and not limiting.

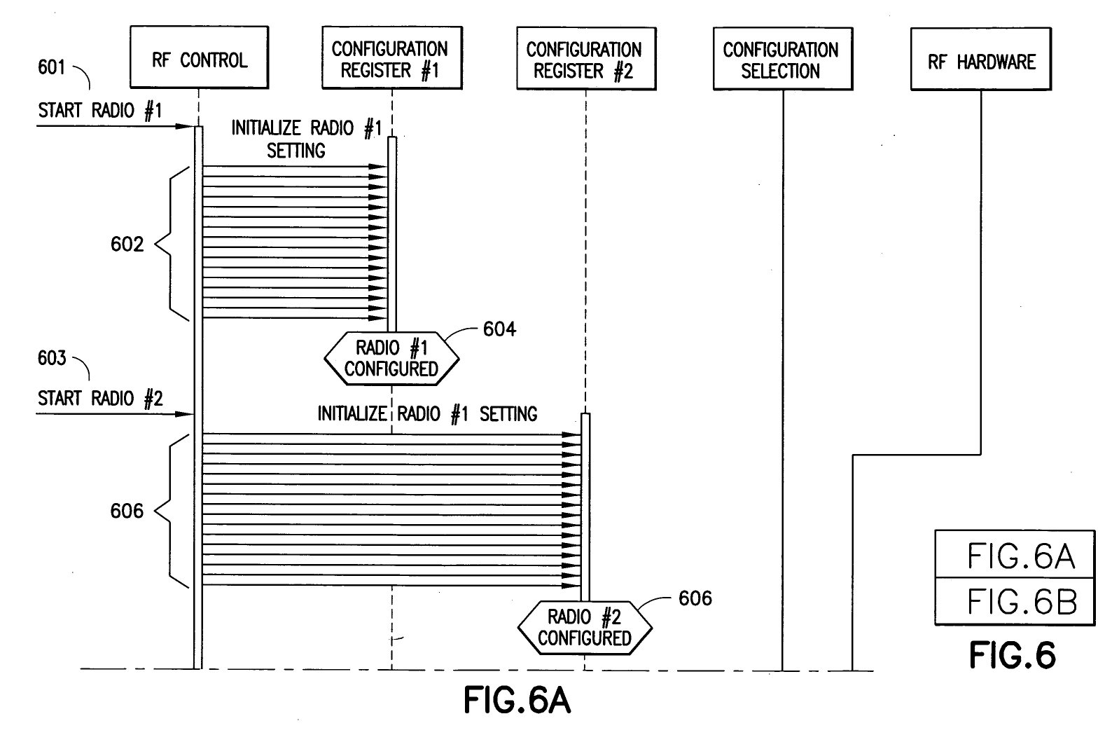

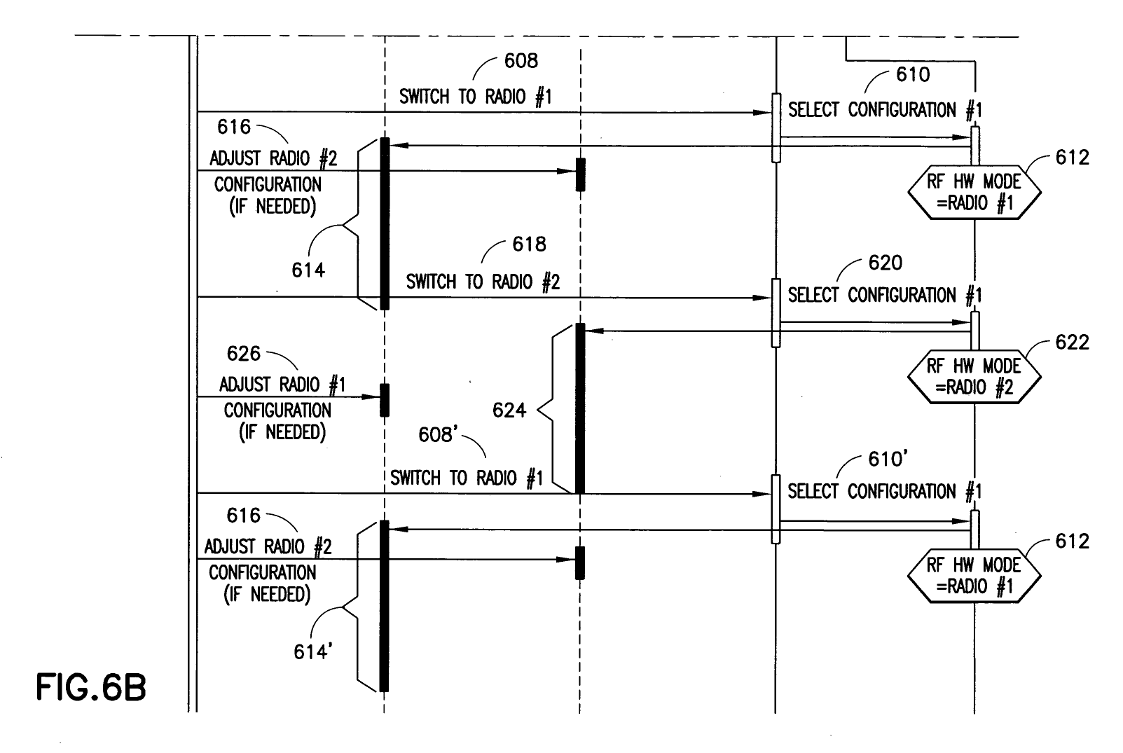

Referring to FIG. 6, consider an example of a multiradio device having two alternating active radio connections, radio #1 and radio #2. At first, when the multiradio device receives a command 601 to start the radio connection using radio system #1, the device initializes the correct hardware configuration for radio #1 to one of its available register banks (the first configuration register set). Typically, the initialization process requires a number of configuration register writes 602. Once the initialization process is completed, radio #1 is ready to be used 604. When the RF control receives the command 603 to start the radio connection using radio system #2, the device writes 606 the configuration setting to another available register bank (the second configuration register set). At this point, the configuration settings for both radio #1 and radio #2 have been written, though as can be seen no radio is active since there is no mode set at the RF HW. Having both configurations written to different configuration register sets allows the RF control to quickly switch the RF HW between radio #1 and radio #2 by selecting one of them as the active configuration. This allows the RF HW context switching to be accomplished rapidly because there is no need to over-write multiple configuration values on the fly as radios are switched.

Now the apparatus switches 608 to radio 1; the configuration selector selects 610 the first configuration register set and the RF HW including the shared HW is configured to the mode 612 of radio 1. Radio 1 remains active 614 for the period indicated, during which time parameters in the second register set can be updated 616 as necessary. A decision is made to switch to radio 2 at 618. The configuration selector selects 620 the second register set, the RF HW is configured to the mode 622 of radio 2, and radio 2 remains active 624 for the indicated period during which any updates 626 may be made to the parameters for radio 1 in the first register set. The apparatus switches back 608′ to radio 1; the configuration selector again selects 610′ the first configuration register set and the RF HW including the shared HW is configured back to the mode 612′ of radio 1. Radio 1 remains active 614′ for the period indicated, during which time parameters in the second register set can be again updated 616′ as necessary.

It should be appreciated that if there is a need to make a modification to the configuration setting (e.g. a change in the gain setting or calibration values), the changes can be performed while the configuration register set is not selected. Thus, modifications are not time critical any longer and can be performed whenever the radio is inactive. For example, consider the situation where the RF HW has 50 16-bit wide configuration registers connected with an RF control device via a serial bus having a clock frequency of 19.2 MHz. Furthermore, assume that the wireless radio system overhead of the serial bus is 14 bits per each 16-bit register write, thus the total number of bits to be transferred for each configuration register write is 30. As can be seen, with the fast context switching scheme of the present invention, one configuration register write operation takes 1.56 microseconds (30*(1/19.2 MHz)), as opposed to the traditional method of context switching which typically takes over 78 microseconds. Thus, when the GSM slot time is about 577 microseconds, the context switch overhead is approximately 13.5% compared to the time the RF HW is actually needed. While with the fast context switching scheme of the present invention, only one register write is needed so the context switch overhead is less than 0.3% compared to the time the RF HW is actually needed.

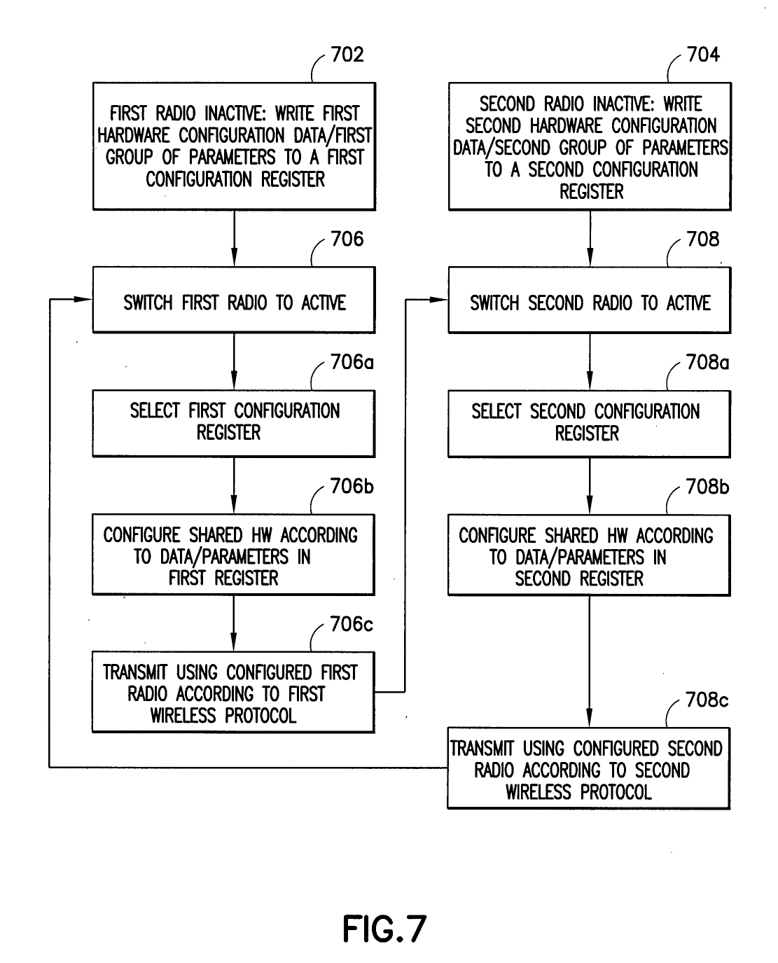

As seen in FIG. 7, while the first radio is inactive, the first hardware configuration (alternatively termed the first group of configuration parameters) is written 702 to the first configuration register set. Similarly while the second radio is inactive, the second hardware configuration (alternatively termed the second group of configuration parameters) is written 704 to the second configuration register set. The first radio is switched to active 706 by selecting the first configuration register set 706a, configuring the shared HW according to the data/parameters in the first register set 706b, and then transmitting or receiving using the configured first radio which is now configured according to a first wireless radio system 706c. To switch the second radio to active 708, the second configuration register set is selected 708a, the shared HW is configured according to the data/parameters in the second register set 708b, and then the configured second radio is used to transmit or receive according to a second wireless radio system 708c.

It should be appreciated that the present invention allows for a low-cost multiradio RF HW platform by making the radio context switch time fast in order to allow RF HW sharing. Additionally, the present invention allows for power saving by reducing the amount of configuration information written through the bus. Furthermore, the present invention allows for a reduced RF control processor load and control bus traffic. This releases more capacity for other applications or enables a lower performance processor to be used. The reduced processor load also means potential to lower power, because performance can be traded for lower power (for example by utilizing dynamic voltage and frequency scaling). Additionally, the present invention allows for a low power communication link between the RF control device and the RF HW.

In general, the embodiments of this invention may be implemented in hardware or special purpose circuits, software, logic or any combination thereof. For example, some aspects may be implemented in hardware, while other aspects may be implemented in firmware or software which may be executed by a controller, microprocessor or other computing device, although the invention is not limited thereto. While various aspects of the invention may be illustrated and described as block diagrams, flow charts, or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

Moreover, embodiments of the invention may be practiced in various components such as integrated circuit modules. The design of integrated circuits is by and large a highly automated process. Complex and powerful software tools are available for converting a logic level design into a semiconductor circuit design ready to be etched and formed on a semiconductor substrate.

Programs, such as those provided by Synopsys, Inc. of Mountain View, Calif. and Cadence Design, of San Jose, Calif. automatically route conductors and locate components on a semiconductor chip using well established rules of design as well as libraries of pre-stored design modules. Once the design for a semiconductor circuit has been completed, the resultant design, in a standardized electronic format (e.g., Opus, GDSII, or the like) may be transmitted to a semiconductor fabrication facility or “fab” for fabrication.

Various modifications and adaptations may become apparent to those skilled in the relevant arts in view of the foregoing description, when read in conjunction with the accompanying drawings. However, any and all modifications of the teachings of this invention will still fall within the scope of the embodiments of this invention.

Furthermore, some of the features of the various embodiments of this invention may be used to advantage without the corresponding use of other features. As such, the foregoing description should be considered as merely illustrative of the principles, teachings and exemplary embodiments of this invention, and not in limitation thereof.

What is claimed is:

1. A method, comprising:
providing a device comprising a first radio adapted to operate according to a first wireless radio system and at least a second radio adapted to operate according to a second wireless radio system, the first radio and second radio each comprising shared hardware;
while the first radio is inactive, writing first hardware configuration data for said first radio to a first configuration register set;
while the second radio is inactive, writing second hardware configuration data for said second radio to a second configuration register set;
switching the first radio to active by selecting the first configuration register, configuring at least the shared hardware according to the first hardware configuration data of the first configuration register set, and communicating via the first radio according to the first wireless radio system; and
switching the second radio to active and the first radio to inactive by selecting the second configuration register set, configuring at least the shared hardware according to the second hardware configuration data of the second configuration register set, and communicating via the second radio according to the second wireless radio system.

2. The method of claim 1, further wherein the device comprises a third radio comprising the shared hardware and adapted to operate according to a third wireless radio system, the method further comprising:
while the third radio and said first radio are inactive, writing third hardware configuration data for said third radio to said first configuration register set.

3. The method of claim 2, further comprising:
switching the third radio to active and the second radio to inactive by selecting the first configuration register set, configuring at least the shared hardware according to the third hardware configuration data of the first configuration register set, and communicating via the third radio according to the third wireless radio system.

4. The method of claim 1 wherein writing the first hardware configuration data for said first radio to the first configuration register set is while the second radio is active.

5. The method of claim 1 wherein writing the first hardware configuration data for said first radio to the first configuration register set, and writing the second hardware configuration data for said second radio to the second configuration register set, are each executed prior to switching either of the first radio or the second radio to active.

6. The method of claim 1 further comprising, while the second radio is active, updating at least one parameter of the first hardware configuration data of the first configuration register set.

7. The method of claim 1, wherein each of the first and second hardware configuration data written to the respective first and second configuration register sets comprise parameters for the shared hardware and for hardware of the respective first and second radios that is not shared.

8. The method of claim 1, wherein each of the first and second hardware configuration data comprises at least one gain value for a shared hardware and at least one calibration value for a shared hardware.

9. An apparatus comprising:
a first radio and at least a second radio that share hardware components, the first radio adapted to operate according to a first wireless radio system and the second radio adapted to operate according to a second wireless radio system;
a processor;
a memory coupled to the processor comprising at least a first configuration register set for storing a first group of parameters and a second configuration register set for storing a second group of parameters; and
configuration selection logic coupled to said processor and to said first and second configuration register sets, said configuration selection logic adapted to switch between the first radio being active and the second radio being active by configuring at least the shared hardware according to the group of parameters of the selected first and second configuration register sets.

10. The apparatus of claim 9, further comprising a third radio that shares the hardware component and adapted to operate according to a third wireless radio system;
and wherein the processor is adapted to write a third group of parameters to the first configuration register set while the second radio is active.

11. The apparatus of claim 10, wherein the configuration selection logic is adapted to
switch the third radio to active and the second radio to inactive by selecting the first configuration register set to which was written the third group of parameters so as to configure at least the shared hardware according to the third group of parameters of the selected first configuration register set.

12. The apparatus of claim 9, wherein the processor is adapted to write the first group of parameters to the first configuration register set is while the second radio is active.

13. The apparatus of claim 9, wherein the processor is adapted to write the first group of parameters to the first configuration register set, and to write the second group of parameters to the second configuration register set, prior to the configuration selection logic switching either of the first radio or the second radio to active.

14. The apparatus of claim 9, wherein the processor is adapted, while the second radio is active, to update at least one parameter of the first group of parameters in the first configuration register set.

15. The apparatus of claim 9, wherein each of the first and second group of parameters comprise parameters for the shared hardware components and for additional hardware components of the respective first and second radios that is not shared.

16. The apparatus of claim 9, wherein each of the first and second groups of parameters comprises at least one gain value for a shared hardware component and at least one calibration value for a shared hardware component.

17. A computer program product comprising program instructions embodied on a tangible computer-readable medium for switching between a first and a second radio that shares hardware, execution of the program instructions resulting in operations comprising:
while a first radio adapted to operate according to a first wireless radio system is inactive, writing first hardware configuration data for said first radio to a first configuration register set;
while a second radio adapted to operate according to a second wireless radio system is inactive, writing second hardware configuration data for said second radio to a second configuration register set;
switching the first radio to active by selecting the first configuration register, configuring at least the shared hardware according to the first hardware configuration data of the first configuration register set, and communicating via the first radio according to the first wireless radio system; and
switching the second radio to active and the first radio to inactive by selecting the second configuration register set, configuring at least the shared hardware according to the second hardware configuration data of the second configuration register set, and communicating via the second radio according to the second wireless radio system.

18. The computer program product of claim 17, the actions further comprising:
while the first radio and a third radio adapted to operate according to a third wireless radio system are inactive, writing third hardware configuration data for said third radio to said first configuration register set.

19. The computer program product of claim 18, the actions further comprising:
switching the third radio to active and the second radio to inactive by selecting the first configuration register set, configuring at least the shared hardware according to the third hardware configuration data of the first configuration register set, and communicating via the third radio according to the third wireless radio system.

20. The computer program product of claim 17, wherein writing the first hardware configuration data for said first radio to the first configuration register set is while the second radio is active.

21. The computer program product of claim 17, wherein writing the first hardware configuration data for said first radio to the first configuration register set, and writing the second hardware configuration data for said second radio to the second configuration register set, are each executed prior to switching either of the first radio or the second radio to active.

22. The computer program product of claim 17, the actions further comprising, while the second radio is active, updating at least one parameter of the first hardware configuration data of the first configuration register set.

23. The computer program product of claim 17, wherein each of the first and second hardware configuration data written to the respective first and second configuration register sets comprise parameters for the shared hardware and for hardware of the respective first and second radios that is not shared.

24. The computer program product of claim 17, wherein each of the first and second hardware configuration data comprises at least one gain value for a shared hardware and at least one calibration value for a shared hardware.

25. A device comprising:
a memory comprising a first configuration register set and a second configuration register set;
shared hardware selectively configurable for a first wireless radio radio system and for at least a second wireless radio radio system;
a controller configured to write first hardware configuration data to the first configuration register set and to write second hardware configuration data to the second configuration register set; and
a configuration selection switch adapted to selectively couple the first and the second configuration register sets to the shared hardware and thereby configure the shared hardware with the first hardware configuration data for communication according to the first wireless radio system and with the second hardware configuration data for communication according to the second wireless radio system.

26. The device of claim 25, wherein the controller is configured to write the first hardware configuration data to the first configuration register set when the configuration selection switch couples the second configuration register set to the shared hardware, and to write the second hardware configuration data to the second configuration register set when the configuration selection switch couples the first configuration register set to the shared hardware.

27. An apparatus comprising:
first radio means and at least second radio means that share hardware components with one another, the first radio means adapted to operate according to a first wireless radio system and the second radio means adapted to operate according to a second wireless radio system;
processing means;
memory means coupled to the processing means, said memory means comprising at least a first register means for storing a first group of parameters and a second register means for storing a second group of parameters; and
selection means coupled to said processing means and to said first and second register means, said selection means adapted to switch between the first radio means being active and the second radio means being active by configuring at least the shared hardware components according to the group of parameters of the selected first and second register means.

28. The apparatus of claim 27, wherein:
the first radio means comprises a first radio;
the second radio means comprises a second radio;
the processing means comprises a digital data processor;
the memory means comprises a computer readable memory;
the first register means comprises a first configuration register set;
the second register means comprises a second configuration register set; and
the selection means comprises a switch.
